(19) United States
(12) Patent Application Publication
(10) Pub. No.: US 2023/0132123 A1
(43) Pub. Date: Apr. 27, 2023

(54) SOLDER TRENCH

(71) Applicant: NOKIA TECHNOLOGIES OY, Espoo (FI)

(72) Inventors: Paul Brown, Wakefield (CA); Alex Chan, Ottawa (CA)

(21) Appl. No.: 17/998,482

(22) PCT Filed: May 12, 2021
(86) PCT No.: PCT/US2021/031914

§ 371 Date: Nov. 10, 2022

Related U.S. Application Data
(60) Provisional application No. 63/024,854, filed on May 14, 2020.

(51) Int. Cl. H05K 1/02; H05K 1/11; H05K 3/40; H05K 3/00

(52) U.S. Cl. CPC H05K 1/0272; H05K 1/111; H05K 3/4007; H05K 3/0026; H05K 2201/09036; H05K 2203/107

(57) ABSTRACT

A printed circuit board structure is disclosed for providing reliable solderability for higher density component placement. The printed circuit board structure includes conductive points disposed on the surface of a printed circuit board which are separated by a channel disposed in the surface of the printed circuit board between the conductive points. The conductive points may be surface mount component terminal pads. The printed circuit board structure is particularly useful for overcoming component density limitations related to extremely miniaturized surface mount components known in the art.

### TECHNICAL FIELD

Various exemplary embodiments disclosed herein relate to provisioning of electrical contact separation structures and are particularly concerned with providing electrical separation between conductive elements used by higher density miniaturized components.

### BACKGROUND

As product density continues to increase (both by increased functionality and by product miniaturization) there is a constant drive toward smaller component packaging. This is increasingly evident in the discrete passive packaging evolution where the industry has seen a 4× reduction in component footprint area every few years.

Surface mount resistors and capacitors of size 0805 used to be among the smallest discrete parts used on a board, but they have subsequently given way to 0402 components and then 0201 components, and now 01005 components. By way of reference, this naming convention describes approximate length and width of the part in thousandths of an inch per Imperial component sizes, and the same concerns are present for corresponding Metric surface mount components. As a consequence of this reduction, an 0402 component would be approximately 0.040″×0.020″, which for comparison is about the size of the letter “o” when displayed in font size 5.

One can easily see the progression from 0402 to 0201 as being a halving of both length and width, with the resulting area occupied by the part being on quarter of that of its predecessor.

Referring to FIG. 1 there may be seen a depiction of 01005 components 100 in relation to the eye 105 of a sewing needle. As the part size shrinks the relative influence of external forces and existing printed circuit board features is increasing, further complicating the challenge of soldering these parts that can be no bigger than a typical grain of salt.

### SUMMARY

A summary of various exemplary embodiments is presented below. Some simplifications and omissions may be made in the following summary, which is intended to highlight and introduce some aspects of the various exemplary embodiments, but not to limit the scope of the invention. Detailed descriptions of an exemplary embodiment adequate to allow those of ordinary skill in the art to make and use the inventive concepts will follow in later sections.

Means for disposing channel-like structures between conductive points on a printed circuit board are disclosed. Benefits of embodiments may include: enhancing reliability of surface mount component soldering, in particular when very small size surface mount components are soldered.

According to an aspect of the embodiments described herein there is provided a printed circuit board for mounting electrical components thereupon, the printed circuit board having a first side; at least two conductive points located on the first side; and a channel in the surface of the first side between the at least two conductive points. According to an aspect of this embodiment the at least two conductive points are solderable terminal pads. In some of these embodiments the solderable terminal pads are surface mount component terminal pads. In some of these embodiments the channel was formed in the first side of the printed circuit board by laser ablation.

In accordance with another aspect of the embodiments described herein there is provided a method of manufacturing a printed circuit board for mounting electrical components upon a first side thereof having the steps of: forming a least two conductive points located on the first side; and excavating a channel in the surface of the first side between the at least two solderable terminal pads. According to an aspect of this embodiment the channel was formed in the first side of the printed circuit board by laser ablation. According to another aspect of this embodiment the conductive points are solderable terminal pads. In some of these embodiments the solderable terminal pads are surface mount component terminal pads.

Various embodiments relate to a printed circuit board for mounting electrical components thereupon including: a first side; at least two neighboring conductive pads located on the first side; and a channel in the surface of the first side between the at least two neighboring conductive pads.

Various embodiments are described, wherein the channel was formed in the first side by laser ablation.

Various embodiments are described, wherein the at least two terminal pads are surface mount component terminal pads.

Various embodiments are described, further including: a solder mask barrier on the first side surrounding the two neighboring conductive pads and the channel.

Various embodiments are described, further including: a surface mount component soldered to the two neighboring conductive pads.

Various embodiments are described, wherein the trench has a width spanning distance between the two neighboring conductive pads.

Various embodiments are described, wherein the trench has a width less than a distance between the two neighboring conductive pads.

Various embodiments are described, wherein the trench has a length approximately equal to or greater than a width of the two neighboring conductive pads.

Various embodiments are described, wherein the trench has a volume configured to hold enough solder flow to prevent the solder flow from shorting the two neighboring conductive pads.

Further various embodiments relate to a method of manufacturing a printed circuit board for mounting electrical components upon a first side including the steps of: forming a least two neighboring conductive pads located on the first side; and excavating a channel in the surface of the first side between the at least two neighboring conductive pads.

Various embodiments are described, wherein the excavating step is performed by laser ablation.

Various embodiments are described, wherein the two neighboring terminal pads are surface mount component terminal pads.

Various embodiments are described, further including: forming a solder mask barrier on the first side surrounding the two neighboring conductive pads and the channel.

Various embodiments are described, further including: soldering a surface mount component to the two neighboring conductive pads.

Various embodiments are described, wherein soldering a surface mount component to the two neighboring conductive pads further includes: applying solder paste on the two neighboring conductive pads; placing a surface mount component on the solder paste on the two neighboring conductive pads; and reflowing the solder paste.

Various embodiments are described, wherein the trench has a width spanning distance between the two neighboring conductive pads.

Various embodiments are described, wherein the trench has a width less than a distance between the two neighboring conductive pads.

Various embodiments are described, wherein the trench has a length approximately equal to or greater than a width of the two neighboring conductive pads.

Various embodiments are described, wherein the trench has a volume configured to hold enough solder flow to prevent the solder flow from shorting the two neighboring conductive pads.

### BRIEF DESCRIPTION OF THE DRAWINGS

In order to better understand various exemplary embodiments, reference is made to the accompanying drawings, wherein:

FIG. 1 illustrates a view of a several 01005 surface mount components in proximity to sewing needles for scale conveyance purposes;

FIGS. 2A and 2B illustrate a close-up combined top view and profile view of a set of terminal pads for a surface mount component;

FIGS. 3A and 3B illustrate the set of terminal pads of FIGS. 2A and 2B with a post-soldering operation surface mount component attached thereon;

FIGS. 4A and 4B illustrate a close-up combined top view and profile view of an alternate set of terminal pads for a surface mount component;

FIGS. 5A and 5B illustrate the set of terminal pads of FIGS. 4A and 4B with a post-soldering operation surface mount component attached thereon;

FIGS. 6A and 6B illustrate a close-up combined top view and profile view of a set of terminal pads according to an embodiment for a surface mount component; and

FIG. 7 illustrates the set of terminal pads of FIG. 6A with a post-soldering operation surface mount component attached thereon.

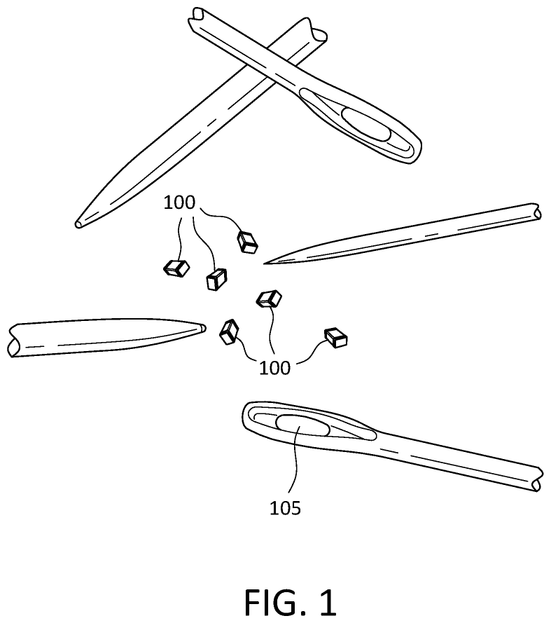

To facilitate understanding, identical reference numerals have been used to designate elements having substantially the same or similar structure and/or substantially the same or similar function.

### DETAILED DESCRIPTION

The description and drawings illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be for pedagogical purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments can be combined with one or more other embodiments to form new embodiments.

One of key challenges in assembling small parts during surface mount assembly is ensuring that the solder-paste forms good solder joints on each of the independent terminals without bridging over to the adjacent terminal. With larger parts, it has been a practice to leave a web of solder-mask to form a solder-mask dam between the two terminals as a physical barrier to solder bridging. This physical barrier limits flow of the solder paste during a reflow operation to prevent shorts. Solder-mask, as the name implies, is an epoxy based coating on the printed circuit boards that has historically served as a mask (or physical barrier) to solder.

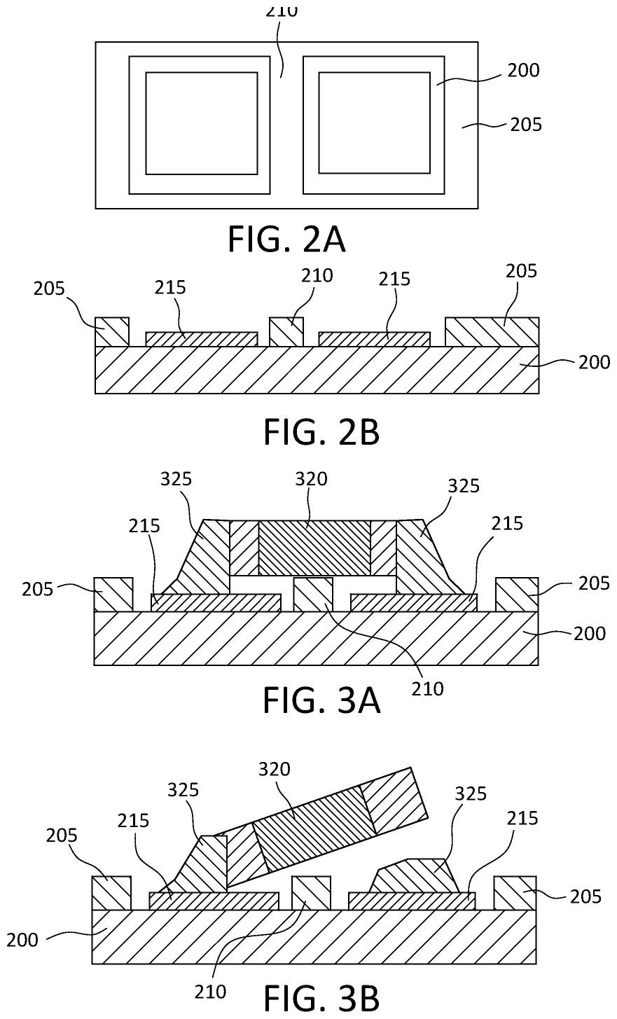

In practice, at these smaller part sizes, the physical separation between these terminal pads is nearing the definition limit for a solder-mask web. Referring now to FIGS. 2A and 2B there may be seen a set of neighboring terminal pads 215 for surface mount components having solder-mask 205 surrounding the pads with a solder dam 210 occupying the space between the terminal pads. The set of neighboring terminal pads 215 are adjacent to one another on the surface of the board without any other conductive structures on the surface of the board between them. Terminal pads 215 may be formed on the board 200 using known processes. Also the solder mask 205 is formed on the board 200 using known processes to form a barrier to solder flowing into undesired areas. A center portion of the solder mask 205 forms the solder dam 210 between the two pads 215 so as to prevent solder from either pad flowing towards the other pad and to prevent the creation of a short between the pads due to solder flow.

Referring to FIG. 3A there may be seen a surface mount component 320 soldered to the neighboring terminal pads 215 depicted in FIGS. 2A and 2B. Solder 325 connects the terminals of the surface mount component 320 to the terminal pads 215. The surface mount component 320 may be seen spanning atop the solder-mask dam 210 between the terminal pads 215. An additional difficulty at these small dimensions is that the thickness of the solder-mask 205 itself, which is insignificant on larger part sizes, presents a formidable step for these smaller parts to span, leading to increased risk of “tombstoning” as depicted in FIG. 3B. In FIG. 3B the solder-mask dam 210 is tall enough so that the surface mount component 320 connects to the solder 325 on the left, but is unable to connect to the solder 325 on the right because of placement asymmetries and differences in surface tension of the solder on each terminal pad. This leads to a failure of the board being constructed.

For these reasons a solder-mask web including a solder-mask dam is increasingly no longer practical solution to preventing shorting during assembly of these tiny discrete components.

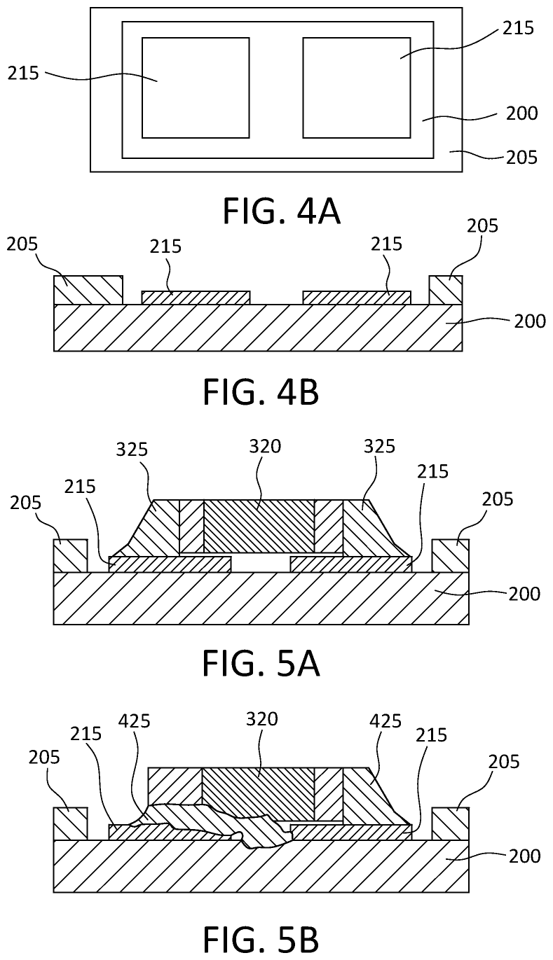

However, forgoing the use of solder-mask altogether and relying on the physical spacing of the two solder terminals as an impediment to solder-bridging between the terminal pads has its own problems. Referring to FIGS. 4A and 4B there may be seen an alternate set of neighboring terminal pads 215 for surface mount components lacking a solder-mask dam occupying the space between the terminal pads 215. In this case the solder mask 205 surrounds the outside of the terminal pads 215 without having a portion in between the pads.

Referring to FIG. 5A there may be seen a surface mount component 320 soldered to the terminal pads 215 depicted in FIGS. 4A and 4B. As may be seen in FIG. 5A, the soldered surface mount component 320 spans the space between the terminal pads 215 and has a position low to the surface of the board 200 as it does not have to bridge any solder-mask dam. However, as may be seen in FIG. 5B, the lack of a solder-mask dam eliminates the barrier to solder-bridging between the terminal pads, enabling the formation of solder-bridging faults. The solder 425 on the left is show as flowing between the terminal pads 215 to cause a short between the terminal pads 215.

Accordingly, what is required is some means of inhibiting the likelihood of solder-bridges between terminal pads at dimensions for which solder-mask web structures are ill suited.

Laser ablation is the process of removing material by irradiating it with a laser beam. Laser drilling, a type of laser ablation, is a process for creating through-holes by repeatedly pulsing focused laser energy on a material. The diameter of these holes can be as small as 0.002″. Laser drilling is one of the few techniques for producing high-aspect-ratio holes—holes with a depth-to-diameter ratio much greater than 10:1. Laser-drilled high-aspect-ratio holes are used in many applications, including the oil gallery of some engine blocks, aerospace turbine-engine cooling holes, laser fusion components, and printed circuit board micro-vias.

According to an embodiment, laser ablation is used, not to drill holes, but to create “trenches” or “channels” between the component terminals on the printed circuit board. The scale and accuracy of the laser ablation technology which has been developed for printed circuit board micro-via formation is such that it may be adapted to form these “solder trenches”. The result is a solution which greatly reduces the risk of solder bridging without addition of any material which would have to be bridged by the surface mount component.

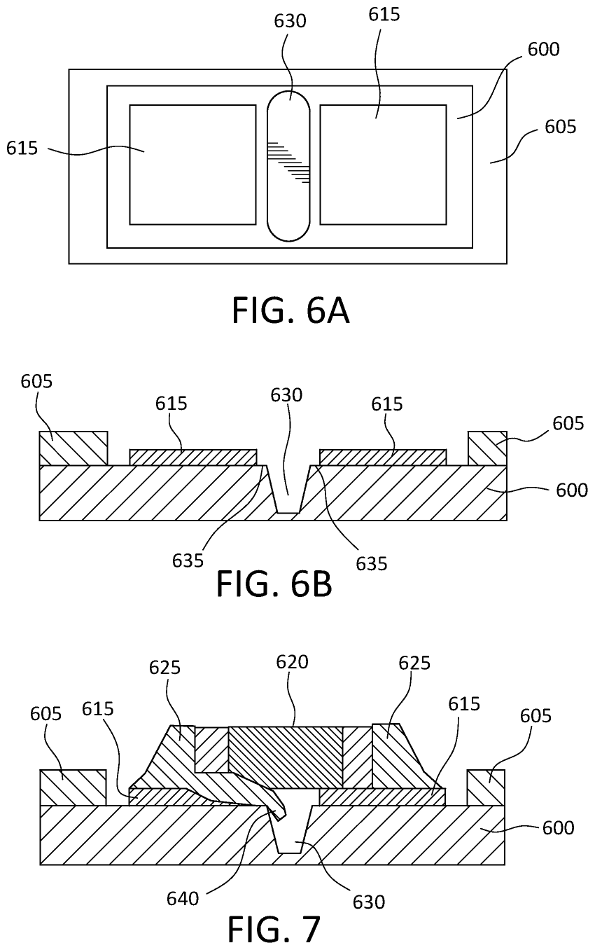

Referring now to FIGS. 6A and 6B, there may be seen a set of terminal pads 615 for surface mount components according to an embodiment. FIG. 6A provides a top view of the terminal pads 615 formed on a board 600, and FIG. 6B provides a profile view. It may be seen that the terminal pads 615 of FIGS. 6A and 6B lack a solder-mask dam occupying the space between the terminal pads 615. Again solder mask 605 surrounds both terminal pads 615 in order to limit the flow of the solder used to connect surface mount components to the terminal pads 615.

Also, a trench-like formation or channel 630 situated between the terminal pads 615 may be seen in FIGS. 6A and 6B. This trench-like formation or channel 630 in formed the circuit board 600 material situated between the two terminal pads 615 and has a channel length generally or approximately the same as or greater than the width of the terminal pads 615. The channel 630 may be formed in the circuit board by laser ablation. Other forms of precisely controlled material removal may also be used to from the channel 630, for example plasma etching. The channel 630 takes the place of a conventional solder-mask dam and provides the necessary barrier to solder spreading beyond its intended application surface.

The channel formation can take advantage of two key properties of laser ablation: very narrow ablation width and the laser's ability to easily ablate laminate material used to manufacture the board 600 while leaving adjacent copper features relatively untouched. The combination of these properties eliminates any risk of misregistration or concerns for minimum solder-resist web definition. Further, a copper layer stopper (not shown) may be placed below a laminate layer to be trenched by laser ablation, and the underlying copper layer stopper is resistant to the laser ablation and prevents the trench from being too deep. Further, the channel 630 may be sized to have a volume to hold any solder that flows from the terminal pads 615 during the reflow operation.

As a result of the laser's accuracy, the channel 630 may be defined with a slight setback 635 from the solderable terminal pads 615 as shown in FIGS. 6A and 6B. In this case, the width of the trench is less than the width of the distance between the terminal pads 615. In an alternate embodiment, the channel 630 may span the entire distance between the solderable terminal pads 615, using the terminal pad 615 surface itself as a stop.

Referring to FIG. 7, there may be seen a surface mount component 620 soldered to the terminal pads 615 using solder 625 as depicted in FIGS. 6A and 6B. In FIG. 7, it may be seen that the channel 630 between the solderable terminal pads interrupts the progression of the solder bridge 640 such that it does not bridge the two terminal pads 615. Thus, the presence of the channel 630 operates to minimize solder-bridge formation, yet avoids the tombstoning problems incurred by an intervening solder-mask dam.

Accordingly, what has been described provides using a printed circuit board fabrication laser ablation process to construct intervening channels between surface mount terminal pads on the printed circuit board surface. These channels have particular application in respect of highly miniaturized surface mount components, such as the 01005 series of surface mount components, however these channels may also advantageously be deployed in other areas of the printed circuit board where proximity considerations make the use of channels relevant.

The anticipated usage of the 01005 and comparably dimensioned components is extensive and applies to virtually every facet of modern electronics; from mobile phones to hearing aids, miniaturized medical applications, and apparatus intended for remote deployment in the Internet of Things.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the claims.

What is claimed is:

1. A printed circuit board for mounting electrical components thereupon comprising:
a first side;
at least two neighboring conductive pads located on the first side; and
a channel in the surface of the first side between the at least two neighboring conductive pads.

2. The printed circuit board of claim 1, wherein
the channel was formed in the first side by laser ablation.

3. The printed circuit board of claim 2, wherein
the at least two terminal pads are surface mount component terminal pads.

4. The printed circuit board of claim 1, further comprising:
a solder mask barrier on the first side surrounding the two neighboring conductive pads and the channel.

5. The printed circuit board of claim 1, further comprising:
a surface mount component soldered to the two neighboring conductive pads.

6. The printed circuit board of claim 1, wherein the trench has a width spanning distance between the two neighboring conductive pads.

7. The printed circuit board of claim 1, wherein the trench has a width less than a distance between the two neighboring conductive pads.

8. The printed circuit board of claim 1, wherein the trench has a length approximately equal to or greater than a width of the two neighboring conductive pads.

9. The printed circuit board of claim 1, wherein the trench has a volume configured to hold enough solder flow to prevent the solder flow from shorting the two neighboring conductive pads.

10. A method of manufacturing a printed circuit board for mounting electrical components upon a first side comprising the steps of:
forming a least two neighboring conductive pads located on the first side; and
excavating a channel in the surface of the first side between the at least two neighboring conductive pads.

11. The method of claim 10, wherein
the excavating step is performed by laser ablation.

12. The method of claim 11, wherein
the two neighboring terminal pads are surface mount component terminal pads.

13. The method of claim 10, further comprising:
forming a solder mask barrier on the first side surrounding the two neighboring conductive pads and the channel.

14. The method of claim 10, further comprising:
soldering a surface mount component to the two neighboring conductive pads.

15. The method of claim 10, wherein soldering a surface mount component to the two neighboring conductive pads further comprises:
applying solder paste on the two neighboring conductive pads.
placing a surface mount component on the solder paste on the two neighboring conductive pads; and
reflowing the solder paste.

16. The method of claim 10, wherein the trench has a width spanning distance between the two neighboring conductive pads.

17. The method of claim 10, wherein the trench has a width less than a distance between the two neighboring conductive pads.

18. The method of claim 10, wherein the trench has a length approximately equal to or greater than a width of the two neighboring conductive pads.

19. The method of claim 10, wherein the trench has a volume configured to hold enough solder flow to prevent the solder flow from shorting the two neighboring conductive pads.
